(19) United States
(12) Patent Application Publication
(10) Pub. No.: US 2024/0423086 A1
(43) Pub. Date: Dec. 19, 2024

(54) LIGHT-EMITTING ELEMENT AND METHOD FOR PRODUCING SAME

(71) Applicant: Sharp Display Technology Corporation, Kameyama City, Mie (JP)

(72) Inventors: Hirofumi YOSHIKAWA, Kameyama City, Mie (JP); Kazuki GOTO, Kameyama City, Mie (JP); Yoshihiro UETA, Kameyama City, Mie (JP)

(21) Appl. No.: 18/702,239

(22) PCT Filed: Dec. 29, 2021
(86) PCT No.: PCT/JP2021/049018

§ 371 Date: Apr. 17, 2024

(51) Int. Cl. H10K 85/30; B82Y 20/00; C09K 11/02; H10K 50/115; H10K 71/12

(52) U.S. Cl. CPC H10K 85/381; C09K 11/025; H10K 50/115; H10K 71/12; B82Y 20/00

(57) ABSTRACT

A light-emitting element includes an EML including a QD, a halogen ligand including a halogen element, and a plurality of types of organic ligands composed of organic compounds.

### TECHNICAL FIELD

The disclosure relates to a light-emitting element provided with a light-emitting layer including quantum dots and a method for manufacturing the same.

### BACKGROUND ART

On the surface of a quantum dot, a ligand is generally provided for the purpose of protecting the quantum dot and improving dispersibility of the quantum dot in a solvent. As the ligand, an organic ligand is generally used. Conversely, in recent years, an inorganic ligand has attracted attention as a ligand replacing the organic ligand.

The inorganic ligand has higher stability than that of the organic ligand and can stably protect the surface of a quantum dot. For example, PTL 1 discloses a stable nanostructure composition including a nanostructure and, as the inorganic ligand, a specific fluoride-containing ligand or fluoride anion. PTL 1 exemplifies a quantum dot as one type of the nanostructure.

PTL 1 discloses that when an organic ligand is replaced with an inorganic ligand, the electrochemical stability of a nanostructure-ligand complex is improved to increase the operating life of an electroluminescent device such as a light-emitting diode (that is, a light-emitting element).

### CITATION LIST

### Patent Literature

PTL 1: JP 2020-180278 A

### SUMMARY

### Technical Problem

In this way, in a light-emitting element provided with a light-emitting layer including quantum dots, when the surface of a quantum dot is treated with an inorganic ligand such as a fluoride-based ligand, it is possible to improve reliability of the light-emitting element.

However, as a result of intensive studies by the present inventors, it has been found that high external quantum efficiency cannot be obtained only by treating the surface of a quantum dot with an inorganic ligand such as the fluoride-based ligand.

An aspect of the disclosure has been made in view of the above-mentioned problem, and an object of the disclosure is to provide a light-emitting element capable of achieving high external quantum efficiency and a method for manufacturing the same.

### Solution to Problem

To solve the above problem, a light-emitting element according to an aspect of the disclosure includes a light-emitting layer including a quantum dot, a halogen element, and a plurality of types of organic compounds.

To solve the above problem, a method for manufacturing a light-emitting element according to an aspect of the disclosure includes: performing an organic compound substitution treatment of mixing a first quantum dot dispersion including quantum dots and a first organic compound with a second organic compound to substitute a part of the first organic compound with the second organic compound to produce a second quantum dot dispersion including the quantum dots and a plurality of types of organic compounds including the first organic compound and the second organic compound; performing a halogen element substitution treatment of mixing the second quantum dot dispersion with a solution containing a halogen element to substitute a part of the plurality of types of organic compounds including the first organic compound and the second organic compound with the halogen element to produce a third quantum dot dispersion including the quantum dots, the plurality of types of organic compounds including the first organic compound and the second organic compound, and the halogen element; and performing light-emitting layer formation of using the third quantum dot dispersion to form a light-emitting layer including the quantum dots, the halogen element, and the plurality of types of organic compounds.

### Advantageous Effects of Disclosure

According to an aspect of the disclosure, it is possible to provide a light-emitting element capable of achieving high external quantum efficiency and a method for manufacturing the same.

### BRIEF DESCRIPTION OF DRAWINGS

FIG. 1 is a view illustrating an example of a layered structure of a light-emitting element according to a first embodiment.

FIG. 2 is a partially enlarged cross-sectional view schematically illustrating a schematic configuration of a main part of the light-emitting element according to the first embodiment.

FIG. 3 is a cross-sectional view schematically illustrating an example of a quantum dot according to the first embodiment.

FIG. 4 is a partially enlarged cross-sectional view schematically illustrating a schematic configuration of a main part of a light-emitting element for comparison in which only a first organic ligand is used as a ligand on the surface of a quantum dot.

FIG. 5 is a cross-sectional view schematically illustrating, with arrows, carrier paths in a light-emitting layer of the light-emitting element for comparison illustrated in FIG. 4.

FIG. 6 is a cross-sectional view schematically illustrating, with arrows, carrier paths in a light-emitting layer of the light-emitting element illustrated in FIG. 2.

FIG. 7 is a flowchart illustrating an example of an overview of a method for manufacturing a light-emitting element according to the first embodiment.

FIG. 8 is a flowchart illustrating an example of a quantum dot dispersion production step illustrated in FIG. 7.

FIG. 9 is a graph showing external quantum efficiency with respect to current density of a light-emitting element according to an example of the first embodiment and the light-emitting element for comparison.

FIG. 10 is a view illustrating an example of a layered structure of a light-emitting element according to a modified example of the first embodiment.

FIG. 11 is a partially enlarged cross-sectional view schematically illustrating a schematic configuration of a main part of the light-emitting element according to the modified example of the first embodiment.

### DESCRIPTION OF EMBODIMENTS

### First Embodiment

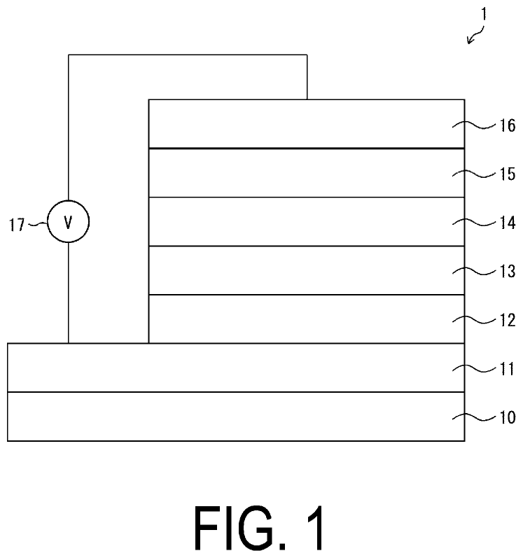

FIG. 1 is a view illustrating an example of a layered structure of a light-emitting element 1 according to the present embodiment.

As illustrated in FIG. 1, the light-emitting element 1 includes an anode electrode 11, a cathode electrode 16, and a function layer provided between the anode electrode 11 and the cathode electrode 16 and including at least a light-emitting layer (hereinafter, denoted by “EML”) 14. Note that, in the present embodiment, the layers between the anode electrode 11 and the cathode electrode 16 are collectively referred to as function layers.

The function layers may be a single layer type formed only of the EML 14, or may be a multi-layer type including other function layers in addition to the EML 14. Of the function layers, examples of function layers other than the EML 14 include a hole injection layer (hereinafter, denoted by “HIL”), a hole transport layer (hereinafter, denoted by “HTL”), and an electron transport layer (hereinafter, denoted by “ETL”).

Note that in the present embodiment, a “lower layer” means a layer that is formed in a process prior to that of a layer to be compared, and an “upper layer” means a layer that is formed in a process after that of a layer to be compared. In the present embodiment, a direction from the anode electrode 11 to the cathode electrode 16 in FIG. 1 is referred to as an upward direction, and the opposite direction thereof is referred to as a downward direction.

Each layer from the anode electrode 11 to the cathode electrode 16 is generally supported by a substrate used as a support body. Accordingly, the light-emitting element 1 may be provided with a substrate as a support body.

As one example, the light-emitting element 1 illustrated in FIG. 1 has a configuration in which a substrate 10, the anode electrode 11, an HIL 12, an HTL 13, the EML 14, an ETL 15, and the cathode electrode 16 are layered in this order towards the upward direction of FIG. 1.

The substrate 10 is a support body for forming the layers from the anode electrode 11 to the cathode electrode 16. The substrate 10 may be, for example, a glass substrate, or may be a flexible substrate such as a plastic substrate or a plastic film.

The light-emitting element 1 may be used as, for example, a light source of a light-emitting device such as a display device. In a case where the light-emitting element 1 is a part of a light-emitting device, a substrate of the light-emitting device is used as the substrate 10. Thus, the light-emitting element 1 may be referred to as the light-emitting element 1 including the substrate 10, or may be referred to as the light-emitting element 1 not including the substrate 10. In a case where the light-emitting element 1 is a part of a display device, for example, an array substrate on which a plurality of thin film transistors are formed may be used as the substrate 10.

The anode electrode 11 and the cathode electrode 16 are connected to a power supply 17 (for example, a DC power supply), whereby a voltage is applied therebetween. The anode electrode 11 and the cathode electrode 16 include a conductive material, and are electrically connected to the HIL 12 and the ETL 15, respectively.

At least one of the anode electrode 11 and the cathode electrode 16 is a light-transmissive electrode. Note that either the anode electrode 11 or the cathode electrode 16 may be a so-called reflective electrode having light reflectivity. In the light-emitting element 1, light can be extracted from the side of the light-transmissive electrode.

For example, in a case where the light-emitting element 1 is a top-emission type light-emitting element that emits light from an upper electrode side, a light-transmissive electrode is used as the upper electrode, and a reflective electrode is used as the lower electrode. On the other hand, in a case where the light-emitting element 1 is a bottom-emission type light-emitting element that emits light from a lower electrode side, a light-transmissive electrode is used as the lower electrode, and a reflective electrode is used as the upper electrode.

The light-transmissive electrode is formed of a conductive light-transmissive material such as indium tin oxide (ITO), indium zinc oxide (IZO), silver nanowire (AgNW), a thin film of magnesium-silver (MgAg) alloy, or a thin film of silver (Ag), for example.

On the other hand, the reflective electrode is formed of a conductive light-reflective material, for example, a metal such as silver (Ag), aluminum (Al), or copper (Cu), or an alloy including these metals. Note that the reflective electrode may be obtained by layering a layer made of the light-transmissive material and a layer made of the light-reflective material.

The HIL 12 is a layer that has hole transport properties and promotes injection of holes from the anode electrode 11 into the HTL 13. As a material for the HIL 12, for example, a hole transport material such as a composite (PEDOT:PSS) of poly(3,4-ethylenedioxythiophene) (PEDOT) and polystyrene sulfonic acid (PSS) is used.

The HTL 13 and the ETL 15 are each provided adjacently to the EML 14.

The HTL 13 is a layer that has hole transport properties and transports holes from the anode electrode 11 to the EML 14. Note that the HTL 13 may have a function of inhibiting transport of electrons. Further, the HTL 13 may also have a function as a hole injection layer (HIL) that promotes the injection of holes from the anode electrode 11 into the EML 14, and the anode electrode 11 may also have a function as the HIL.

A known hole transport material can be used for the HTL 13. Examples of the hole transport material used for the HTL 13 include poly [(9,9-dioctylfluorenyl-2,7-diyl)-co-(4,4′-(N-4-sec-butylphenyl))diphenylamine)] (abbreviated “TFB”), poly [N,N′-bis(4-butylphenyl)-N,N′-bis(phenyl)-benzidine] (abbreviated “p-TPD”), and polyvinyl carbazole (abbreviated “PVK”). Only one type of these hole transport materials may be used, or two or more types thereof may be mixed and used as appropriate.

The ETL 15 is a layer that has electron transport properties and transports electrons from the cathode electrode 16 to the EML 14. Note that the ETL 15 may have a function of inhibiting the transport of holes. Further, the ETL 15 may also have a function as an electron injection layer (EIL) that promotes injection of electrons from the cathode electrode 16 into the EML 14, and the cathode electrode 16 may also have a function as the EIL.

A known electron transporting material can be used for the ETL 15. Examples of the electron transporting material used for the ETL 15 include a metal oxide including at least one element selected from the group consisting of zinc (Zn), magnesium (Mg), titanium (Ti), silicon (Si), tin (Sn), tungsten (W), tantalum (Ta), barium (Ba), zirconium (Zr), aluminum (Al), yttrium (Y), and hafnium (Hf). Only one type of these electron transport materials may be used, or two or more types thereof may be mixed and used as appropriate.

The disclosure is suitably applied in a case where the ETL 15 includes, for example, a zinc oxide including zinc (Zn) and a metal element other than zinc. In addition, the disclosure is particularly suitably applied in a case where the zinc oxide includes, for example, at least one selected from the group consisting of MgZnO, LiZnO, and MgLiZnO. The reason for this will be described below.

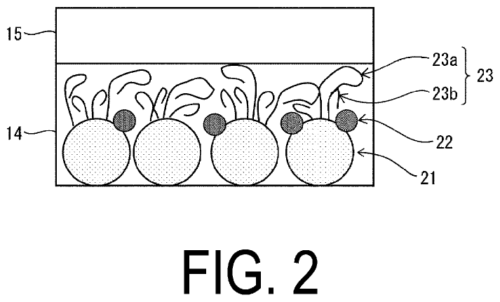

FIG. 2 is a partially enlarged cross-sectional view schematically illustrating a schematic configuration of a main part of the light-emitting element 1 according to the present embodiment.

As illustrated in FIG. 2, the EML 14 is a QD light-emitting layer including quantum dots (hereinafter, denoted by “QD”) 21 as a light-emitting material. In the EML 14, holes transported from the anode electrode 11 and electrons transported from the cathode electrode 16 are recombined by a drive current between the anode electrode 11 and the cathode electrode 16, and light is emitted in a process in which excitons generated by the recombination transit from a conduction band level to a valence band level of the QD 21.

The EML 14 includes the QD 21, a halogen ligand 22 including a halogen element, and a plurality of types of organic ligands 23 composed of organic compounds. This means that the EML 14 includes a halogen element and a plurality of types of organic compounds.

The QD 21 is a dot having a particle maximum width of 100 nm or less. A QD generally has a composition derived from a semiconductor material, and thus may also be referred to as a semiconductor nanoparticle. Further, a QD generally has a composition derived from an inorganic material, and thus may also be referred to as an inorganic nanoparticle. Furthermore, a QD has a structure having a specific crystal structure, for example, and thus may also be referred to as a nanocrystal.

The shape of the QD 21 is not particularly limited as long as it is within a range satisfying the maximum width, and the shape thereof is not limited to a spherical three-dimensional shape (circular cross-sectional shape). The shape of the quantum dot may be, for example, a polygonal cross-sectional shape, a rod-shaped three-dimensional shape, a branch-shaped three-dimensional shape, or a three-dimensional shape having unevenness on the surface thereof, or a combination thereof.

The QD 21 may include, for example, a semiconductor material constituted by at least one element selected from the group consisting of cadmium (Cd), sulfur(S), tellurium (Te), selenium (Se), zinc (Zn), indium (In), nitrogen (N), phosphorus (P), arsenic (As), antimony (Sb), aluminum (Al), gallium (Ga), lead (Pb), silicon (Si), germanium (Ge), and magnesium (Mg).

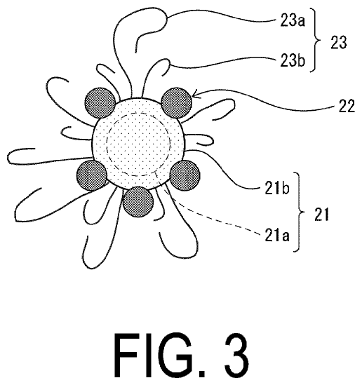

The QD 21 may be formed only of a core, and may be of a two-component core type, of a three-component core type, or of a four-component core type. As illustrated in FIG. 3, the QD 21 may have, for example, a core-shell structure including a core 21a and a shell 21b, and may be of a core-shell type or a core-multi shell type. Note that FIG. 3 is a cross-sectional view schematically illustrating an example of the QD 21. The QD 21 may include a doped nanoparticle, or may have a compositionally graded structure. Further, the shell 21b may be formed in a state of being solid-solved on the surface of the core 21a. In FIG. 3, a boundary between the core 21a and the shell 21b is indicated by a dotted line, and this indicates that the boundary between the core 21a and the shell 21b may be confirmed or need not be confirmed by analysis.

Examples of the material of the QD 21 (materials of the core 21a/shell 21b) may include CdSe/CdS, InP/ZnS, ZnSe/ZnS, and CIGS/ZnS.

In a case where the QD 21 includes the core 21a and the shell 21b and the shell 21b includes at least ZnS, the halogen ligand 22 and the plurality of types of organic ligands 23 can be more stably coordinated to the QD 21. In addition, such a shell 21b becomes a wide-gap shell, and thus it is possible to further exhibit an effect of improving the injection efficiency of carriers by stepwise band line-up.

In a case where the QD 21 includes the shell 21b, it is sufficient for the shell 21b to be provided on the surface of the core 21a. Although it is desirable for the shell 21b to cover the entire core 21a, it is not necessary for the shell 21b to completely cover the core 21a. The shell 21b may be formed on a part of the surface of the core 21a. The QD 21 can be said to have the core-shell structure if it is found that the shell 21b is formed on a part of the surface of the core 21a, or it is found that the shell 21b envelopes the core 21a, in an observation of a cross-section of the QD 21. Accordingly, it is sufficient to determine that the shell 21b covers the entire core 21a by observing a cross-section of the QD 21. Note that the cross-section observation can be performed with, for example, a transmission electron microscope (TEM).

An emission wavelength of the QD 21 can be changed in various ways depending on, for example, a particle size and composition thereof. The QD 21 is a QD that emits visible light, and the emission wavelength can be controlled from a blue wavelength range to a red wavelength range by appropriately adjusting the particle size and composition of the QD 21.

Thus, the QD 21 may be, for example, a blue QD that emits blue light, a green QD that emits green light, or a red QD that emits red light.

Note that the blue light refers to, for example, light having an emission peak wavelength in a wavelength band of equal to or greater than 400 nm and equal to or less than 500 nm. The green light refers to, for example, light having an emission peak wavelength in a wavelength band of greater than 500 nm and equal to or less than 600 nm. The red light refers to light having an emission peak wavelength in a wavelength band greater than 600 nm and equal to or less than 780 nm.

The halogen ligand 22 is not particularly limited as long as it includes a halogen element.

Among them, the halogen ligand 22 including at least one halogen element selected from the group consisting of fluorine (F), chlorine (Cl), and bromine (Br) is suitable as a halogen ligand suitable for a QD that emits visible light. Among them, for example, an F ligand including fluorine as a halogen element is particularly suitable as the halogen ligand 22.

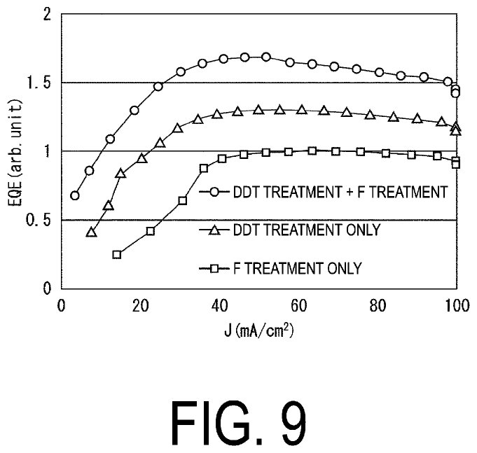

When the surface of the QD 21 is only treated with the halogen ligand 22, the surface of the EML 14 becomes rough, which makes it not possible to achieve high external quantum efficiency (EQE) as shown in FIG. 9 to be described below.

In the present embodiment, as described above, the plurality of types of organic ligands 23 composed of organic compounds are used as the organic ligand. FIG. 2 illustrates an example in which the plurality of types of organic ligands 23 include two types of organic ligands: a first organic ligand 23a and a second organic ligand 23b. Note that FIG. 2 illustrates an example in which the first organic ligand 23a and the second organic ligand 23b are organic ligands composed of linear organic compounds having different molecular chain lengths. The second organic ligand 23b illustrated in FIG. 2 is an organic ligand having a molecular chain length shorter than a molecular chain length of the first organic ligand 23a. However, the present embodiment is not limited thereto, and the plurality of types of organic ligands 23 may include three or more types of organic ligands.

Various known organic ligands may be used as the organic ligands 23. As the organic ligands 23, a ligand having at least one coordinating functional group capable of being coordinated to the QD 21 is used. Typical examples of the coordinating functional group include at least one functional group selected from the group consisting of an amino (—NR₂) group, a phosphonic (—P(═O)(OR)₂) group, a phosphine (—PR₂) group, a phosphine oxide (—P(═O)R₂) group, a carboxyl (—C(═O)OH) group, and a thiol (—SH) group.

Accordingly, the plurality of types of organic compounds contained in the EML 14 preferably include a compound including at least one functional group selected from the group consisting of an amino group, a phosphonic group, a phosphine group, a phosphineoxide group, a carboxyl group, and a thiol group. Note that the phosphine group may be a phosphino (—PH₂) group.

Among the coordinating functional groups, a thiol group has higher coordination properties with respect to a QD, particularly with respect to a QD including Zn, than an amino group, a phosphonic group, a phosphine group, a phosphineoxide group, and a carboxyl group, and can be more stably coordinated to the QD 21. Thus, the plurality of types of organic compounds preferably include a compound including a thiol group.

Examples of the organic ligand 23 include organic compounds such as dodecanethiol, octanethiol, oleylamine, dodecylamine, trioctylphosphine oxide, trioctylphosphine, and tributylphosphine. The plurality of types of organic ligands 23 preferably include at least one compound selected from the group consisting of these exemplified compounds. Thus, the plurality of types of organic compounds included in the EML 14 preferably include at least one compound selected from the group consisting of dodecanethiol, octanethiol, oleylamine, dodecylamine, trioctylphosphine oxide, trioctylphosphine, and tributylphosphine.

Further, the plurality of types of organic compounds more preferably include dodecanethiol. The QD is commercially available, and the commercially available QD is generally provided in the form of a QD dispersion that includes an organic ligand. The QD can be synthesized by any method. For example, a wet method is used for the synthesis of the QD, and the particle size of the QD is controlled by coordinating an organic ligand to the surface of the QD. Note that the organic ligand is used as a dispersing agent for improving dispersibility of the QD in the QD dispersion, and is also used for improving surface stability and storage stability of the QD.

In the present embodiment, as will be described below, a QD synthesized or commercially obtained as the QD 21 is treated with dodecanethiol, for example, and a part of the organic ligand coordinated to the QD is substituted with dodecanethiol (ligand exchange). This can improve the EQE.

Dodecanethiol and octanethiol each include a thiol group as the coordinating functional group and are easily coordinated to the QD 21. Oleylamine and dodecylamine each include an amino group as the coordinating functional group and are easily coordinated to the QD 21. Similarly, trioctylphosphine oxide includes a phosphine oxide group as the coordinating functional group, and trioctylphosphine and tributylphosphine each include a phosphine group as the coordinating functional group, and thus are easily coordinated to the QD 21.

However, the plurality of types of organic compounds used as the organic ligand 23 (in other words, the plurality of types of organic compounds included in the EML 14) are not limited to the organic compounds exemplified above.

Examples of the organic ligand 23 other than the above-exemplified organic ligands 23 include thiol-based organic compounds having a thiol group as the coordinating functional group, such as isobutyl mercaptan, 1-decanethiol, ethyl mercaptan, 1-octadecanethiol, isoamyl mercaptan, 1-hexadecanethiol, 1-undecanethiol, hexyl mercaptan, 1-heptanethiol, 1-pentanethiol, and 1-butanethiol.

Examples of the organic ligand 23 other than the above-exemplified organic ligands 23 include amine-based organic compounds having an amino group as the coordinating functional group, such as 1-aminopentadecane, ethylamine, 2-butyl-n-octan-1-amine, 2-aminopentane, 6-undecanamine, methylamine, 8-pentadecanamine, methylamine, 2-aminooctane, 3-aminopentane, isobutylamine, and 2-n-octyl-1-dodecylamine.

Examples of the organic ligand 23 other than the above-exemplified organic ligands 23 include phosphine-based organic compounds which are phosphorus-based organic compounds having a phosphine group as the coordinating functional group, such as trihexylphosphine, trimethylphosphine, and 1,2-bis(dimethylphosphino)ethane.

Examples of the organic ligand 23 other than the above-exemplified organic ligands 23 include phosphonic acid-based organic compounds which are phosphorus-based organic compounds having a phosphonic group as the coordinating functional group, such as heptylphosphonic acid, butylphosphonic acid, 1,3-propylenediphosphonic acid, undecylphosphonic acid, hexadecylphosphonic acid, methylphosphonic acid, methylenediphosphonic acid, n-octylphosphonic acid, nonylphosphonic acid, 1,4-butylenediphosphonic acid, ethylphosphonic acid, and 1,2-ethylenediphosphonic acid.

Examples of the organic ligand 23 other than the above-exemplified organic ligands 23 include phosphine oxide-based organic compounds which are phosphorus-based organic compounds having a phosphine oxide group as the coordinating functional group, such as tributylphosphine oxide.

Examples of the organic compound other than the organic ligand 23 include carboxylic acid-based organic compounds having a carboxyl group as the coordinating functional group, such as a branched carboxylic acid, a linear saturated carboxylic acid, and a linear unsaturated carboxylic acid.

Examples of the branched carboxylic acid include isostearic acid, 2-ethylhexanoic acid (octanoic acid), isobutyric acid, 2-hexyldecanoic acid, tiglic acid, 2-ethylbutyric acid, isovaleric acid, 3-methylcrotonic acid, DL-2-methylbutyric acid, 2-methyl-2-pentenoic acid, 4-methyl-2-pentenoic acid, and 2-hexadecyloctadecanoic acid.

Examples of the linear saturated carboxylic acid include acetic acid, pentacosanoic acid, valeric acid, nonacosanoic acid, pentadecanoic acid, nonanoic acid, undecanoic acid, nonadecanoic acid, heptanoic acid, heptadecanoic acid, cerotic acid, and behenic acid.

Examples of the linear unsaturated carboxylic acid include 3-heptenoic acid, trans-2-pentenoic acid, 2,4-heptadecadiynoic acid, trans-2-hexenoic acid, 10,12-heptadecadiynoic acid, 2,4-nonadecadiynoic acid, 10-undecenoic acid, ricinoleic acid, 10-undecenoic acid, elaidic acid, petroselinic acid, and 10,12-pentacosadiynoic acid.

These exemplified organic ligands 23 are monomers. Note that in the present embodiment, the monomer refers to a compound having a molecular weight of 1000 or less. A polymer has many repeats of a unit structure (monomer) and generally has about 1,000 or more atoms or is polymerized to have a molecular weight of 10,000 or more. An oligomer has fewer repeats of a unit structure (monomer) and generally has a molecular weight of from 1,000 to 10,000. A polymerized or oligomerized organic ligand consumes the coordinating functional groups and forms a chain by a chemical reaction. Thus, the molecule becomes larger and the number of the coordinating functional groups decreases, thereby decreasing a probability of coordination to the QD 21. Accordingly, although the organic ligand 23 may include an oligomer or a polymer, it is desirable that the organic ligand 23 includes at least a monomer to cover the surface of the QD 21 without gaps.

When types of organic compounds are different, lengths of molecular chains between terminal groups of these organic compounds are different from each other in at least one portions. In other words, lengths of main chains or side chains of these organic compounds are different from each other. Accordingly, the plurality of types of organic compounds used as the organic ligand 23 (in other words, the plurality of types of organic compounds included in the EML 14) have different lengths of the main chains or the side chains.

The plurality of types of organic compounds preferably include a compound having a molecular chain in which a length of a molecular chain between terminal groups is different by 10% or more from a length of any one molecular chain between terminal groups in any one of the plurality of types of organic compounds. The difference in length of the molecular chain between the terminal groups is more preferably 30% or more. That is, it is more preferable that a plurality of types of organic compounds include a compound having a molecular chain in which a length of a molecular chain between terminal groups is different by 30% or more from a length of any one molecular chain between terminal groups in any one of the plurality of types of organic compounds. The difference in length of the molecular chain between the terminal groups is more preferably 50% or more, and particularly 70% or more.

For example, when a molecular chain length of the first organic ligand 23a is taken as a reference (=x), a molecular chain length of the second organic ligand 23b is suitably 0.9× or less, more suitably 0.7× or less, still more suitably 0.5× or less, and particularly suitably 0.3× or less. When a molecular chain length of the second organic ligand 23b is taken as a reference (=y), a molecular chain length of the first organic ligand 23a is suitably 1.1 y or more and 2 y or less, more suitably 1.3 y or more and 2 y or less, still more suitably 1.5 y or more and 2 y or less, particularly suitably 1.7 y or more and 2 y or less. Note that here, for convenience of description, as described above, a case where the first organic ligand 23a and the second organic ligand 23b are each an organic ligand composed of a linear organic compound is simply described as an example. However, the organic ligand 23 may have a branched chain or may have an aromatic ring. Accordingly, one of the molecular chains between the terminal groups of the organic compound to be compared may be a side chain. That is, among the plurality of organic compounds, a length from a coordinating functional group (adsorbing group) to a main chain terminal of one organic compound may be compared with a length from a coordinating functional group (adsorbing group) to a main chain terminal or a side chain terminal of another organic compound.

The plurality of types of organic compounds preferably include an organic compound having 8 to 15 carbon atoms. The organic compound having 8 to 15 carbon atoms is easily available, is suitable as a ligand of the QD, and is generally used as a ligand of such a QD.

Note that the organic compound having 8 to 15 carbon atoms may be an organic compound having a longer molecular chain length between terminal groups to be compared, or may be an organic compound having a shorter molecular chain length between terminal groups to be compared.

Accordingly, a proportion of each organic compound in the organic ligand 23 is not particularly limited. A proportion of each of the halogen ligand 22 and the organic ligand 23 to the total amount of the halogen ligand 22 and the organic ligand 23 included per unit volume in the EML 14 is not particularly limited. In addition, a proportion of each of the halogen ligand 22 and the organic ligand 23 to the QD 21 included per unit volume in the EML 14 is not particularly limited.

As illustrated in FIG. 2, the halogen ligand 22 and the plurality of types of organic ligands 23 are coordinated as ligands on the surface of the QD 21. The presence of the halogen ligand 22 can be confirmed by presence of a halogen element.

In addition, as described above, an organic compound having a coordinating functional group is easily coordinated to the QD 21. Thus, when the organic compounds included in the EML 14 have the above-described coordinating functional group, at least a part of the organic compounds can be regarded as being coordinated to the QD 21.

Note that in the present embodiment, the term “coordination” indicates that a ligand and the surface of the QD 21 interact with each other, and indicates that, for example, the ligand is adsorbed on the surface of the QD 21 (in other words, the ligand modifies the surface of the QD 21 (surface modification)). Note that here, the term “adsorption” indicates that a concentration of the ligand on the surface of the QD 21 is higher than that in the surroundings. The adsorption may be chemical adsorption in which there is a chemical bond between the QD 21 and the ligand, physical adsorption, or electrostatic adsorption.

In the present embodiment, the term “ligand” refers to a molecule or ion that can interact with the surface of the QD 21. The ligand may be bonded by a coordinate bond, a covalent bond, an ionic bond, a hydrogen bond, or the like as long as it can interact with the surface of the QD 21, or the ligand does not necessarily have to be bonded. The interaction may be, for example, coordinative, covalent, ionic, hydrogen bonding interactions, van der Waals interaction, or other molecular interactions. All of the organic compounds exemplified as the organic ligands 23 are molecules capable of interacting with the surface of the QD 21. Note that it goes without saying that the halogen ligand 22 described above can interact with the surface of the QD 21. In the present embodiment, not only a molecule or an ion coordinated to the surface of the QD 21 but also a molecule or an ion that can be coordinated but is not coordinated is referred to as a “ligand”.

The type of the ligand included in the EML 14 can be identified by combining a plurality of analysis methods such as a MALDI-TOF-MS method, an LC-MS/MS method, a TOF-SIMS method, an ICP-AES method, and an NMR method.

A matrix-assisted laser desorption-ionization (MALDI) method is a method in which a matrix mixture is irradiated with a nitrogen laser beam (wavelength=337 nm) to rapidly (for several nsec) heat a portion from the outermost surface to 100 nm to vaporize the matrix mixture.

A time-of-flight mass spectrometry (TOF-MS) method is a method of performing mass spectrometry by utilizing the fact that flight time of ions varies depending on a difference in mass-to-charge ratio m/z value.

A liquid chromatography-mass spectrometry (LC-MS/MS) method is a method for identifying a molecule with an apparatus in which a high performance liquid chromatograph (HPLC) and a triple quadrupole mass spectrometer (MS/MS) are combined. The LC-MS/MS can obtain a further separated mass spectrum by the connected MS unit than that of the LC-MS, and is thus superior to the LC-MS in the identification of molecules.

In the time-of-flight secondary ion mass spectrometry (TOF-SIMS) method, when a sample is irradiated with a primary ion beam under ultra-high vacuum, secondary ions are emitted from an extreme surface (1 to 3 nm) of the sample. The secondary ions are introduced into a time-of-flight (TOF) mass spectrometer to obtain a mass spectrum of the outermost surface of the sample. At this time, a primary ion irradiation amount is reduced to a low level, whereby a surface component can be detected as a molecular ion maintaining a chemical structure or a partially cleaved fragment, and information on the elemental composition or chemical structure of the outermost surface can be obtained.

The inductively coupled plasma atomic emission spectrometry (ICP-AES) method is a method in which an atomized liquid sample is introduced into plasma, and luminescence observed in the plasma is dispersed for each element by a spectroscope to perform qualitative analysis and quantitative analysis of elements, and is mainly used for analysis of metal elements.

The nuclear magnetic resonance (NMR) method is a method in which an atomic nucleus in a state where a magnetic field is applied is irradiated with an electromagnetic wave from the outside and a resonance phenomenon of nuclear spin is observed to analyze a molecular structure of a compound.

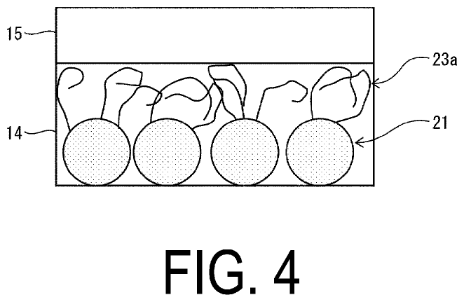

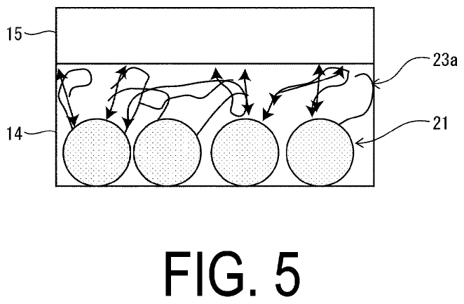

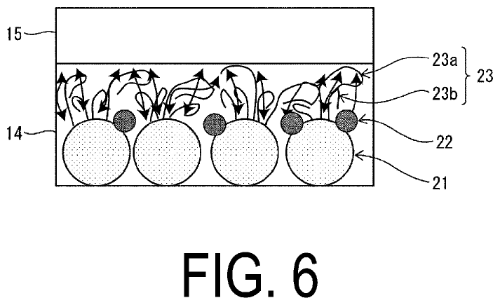

FIG. 4 is a partially enlarged cross-sectional view schematically illustrating a schematic configuration of a main part of a light-emitting element for comparison in which only the first organic ligand 23a is used as a ligand on the surface of the QD 21. FIG. 5 is a cross-sectional view schematically illustrating, with arrows, carrier paths in the EML 14 of the light-emitting element for comparison illustrated in FIG. 4. FIG. 6 is a cross-sectional view schematically illustrating, with arrows, carrier paths in the EML 14 of the light-emitting element 1 illustrated in FIG. 2.

As illustrated in FIG. 4, in a case where only the first organic ligand 23a is coordinated to the surface of the QD 21, many gaps not covered with the ligand are present on the surface of the QD 21.

However, as described above, in the present embodiment, the halogen ligand 22 having a small ligand diameter and the plurality of types of organic ligands 23 having different lengths of the main chains or the side chains are used as the ligands. According to the present embodiment, when the halogen ligand 22 and the plurality of types of organic ligands 23 are used as the ligands in this way, the surface of the QD 21 can be covered with these ligands without gaps as illustrated in FIG. 2.

As a result, irregularities of the surface of the EML 14 can be suppressed and flatness of the surface of the EML 14 can be improved. In addition, when the surface of the QD 21 is covered with these ligands without gaps, surface defects of the EML 14 can be reduced and desorption of the halogen ligand 22 over time can be suppressed, thereby stabilizing surface modification of the QD 21 by the halogen ligand 22. Accordingly, as illustrated in FIG. 6, the carrier paths to a carrier transport layer such as the ETL 15 can be increased as compared with FIG. 5. As described above, according to the present embodiment, carrier mobility between the EML 14 and the carrier transport layer adjacent to the EML 14 can be elevated and the carrier injection efficiency can be improved, whereby the EQE can be improved.

In particular, as described above, in a case where the ETL 15 includes at least one selected from the group consisting of ZnO in which a part of Zn is element-substituted with Li, Mg, or the like, such as MgZnO, LiZnO, and MgLiZnO, the effect of improving the EQE can be further exhibited.

ZnO subjected to element substitution, such as MgZnO, LiZnO, or MgLiZnO, has a small value of a conduction band minimum (CBM) (in other words, the CBM is shallow) and can have a large band gap. Note that here, the value of the CBM indicates the absolute value of a difference in electron energy level between a vacuum level and the conduction band minimum (CBM). Hereinafter, the absolute value of the difference in electron energy level between the vacuum level and a valence band maximum (VBM) is referred to as a value of the VBM.

For example, ZnO has a CBM value of 3.44 eV, a VBM value of 6.84 eV, and a band gap between the CBM and the VBM of 3.4 eV. On the other hand, LiZnO has a CBM value of 3.23 eV, a VBM value of 6.66 eV, and a band gap of 3.42 eV. MgZnO has a CBM value of 3.39 eV, a VBM value of 6.89 eV, and a band gap of 3.5 eV. MgLiZnO has a CBM value of 3.05 eV, a VBM value of 6.60 eV, and a band gap of 3.55 eV. Note that the CBM of the QD 21 is shallower than the CBM of the ETL 15.

When ZnO in which a part of Zn is element-substituted with Li, Mg, or the like is used for the ETL 15 in this way, the CBM becomes shallow and the energy gap between the ETL 15 and the QD 21 becomes close. As a result, an electron injection barrier can be reduced to increase the carrier injection efficiency, and the band gap is increased to improve the electron transport efficiency from the ETL 15 to the EML 14.

On the other hand, the ETL 15 using such ZnO subjected to element substitution is likely to be surface-roughened, and in a case where the ETL 15 is provided on the EML 14 as described above, if the EML 14 has a large surface roughness, the ETL 15 is likely to have a large surface roughness. However, according to the present embodiment, the halogen ligand 22 and the plurality of types of organic ligands 23 are used as the ligands as described above, whereby the flatness of the surface of the EML 14 can be improved and the surface roughness of the ETL 15 as the upper layer thereof can be reduced. Thus, in a case where ZnO subjected to element substitution is used for the ETL 15, it is possible to suppress surface roughing of the ETL 15 and realize the ETL 15 having a shallower CBM and a larger band gap than in a case where ZnO is used for the ETL 15. Accordingly, in a case where ZnO subjected to element substitution is used for the ETL 15, it is possible to improve the electron injection efficiency and further enhance the effect of improving the EQE.

Note that as described above, it goes without saying that when MgLiZnO is used for the ETL 15, the CBM can be made shallower than that in a case where ZnO is used for the ETL 15, and the CBM can be made further shallower as compared with a case where LiZnO and MgZnO are used. Accordingly, it is possible to further enhance the carrier injection efficiency by using MgLiZnO for the ETL 15.

Alternatively, a stack of different materials may be used for the ETL 15. For example, the ETL 15 may have a layered structure of a LiZnO layer and a MgZnO layer. In this case, the band line-up can be made more stepwise, and the carrier injection efficiency can be further enhanced.

### Method for Manufacturing Light-Emitting Element 1

Next, an example of a method for manufacturing the light-emitting element 1 according to the present embodiment will be described. Hereinafter, a method for manufacturing the light-emitting element 1 illustrated in FIG. 1 including the EML 14 illustrated in FIG. 2 will be described as an example.

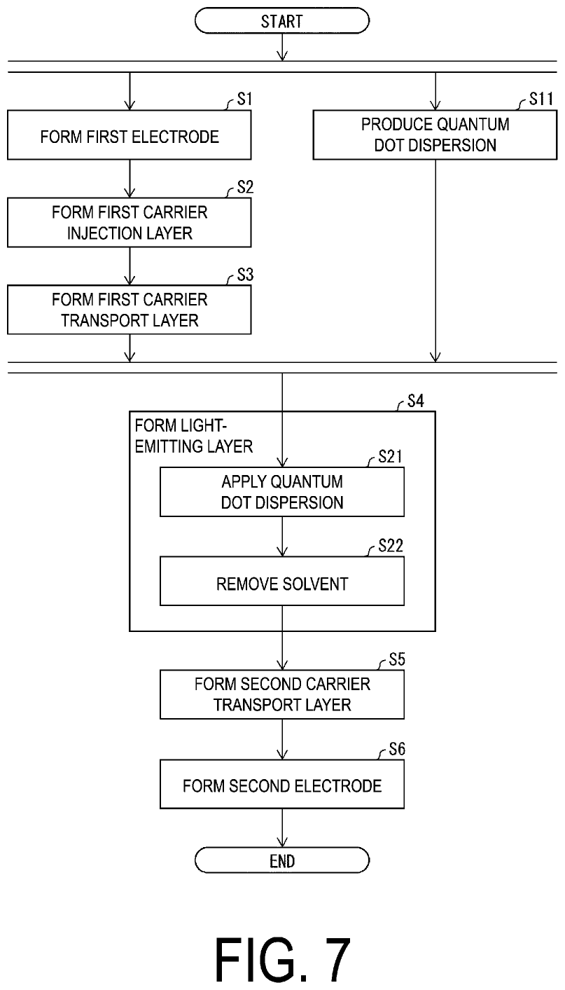

FIG. 7 is a flowchart illustrating an example of an overview of the method for manufacturing the light-emitting element 1 according to the present embodiment. Note that in the following description, for convenience of description, the anode electrode 11 is referred to as a first electrode, the cathode electrode 16 is referred to as a second electrode, a first electrode forming step is an anode electrode forming step, and a second electrode forming step is a cathode electrode forming step. Thus, in the following description, the HTL 13 is referred to as a first carrier transport layer and the ETL 15 is referred to as a second carrier transport layer. However, the order of formation and layering of the anode electrode 11 and the cathode electrode 16 is not particularly limited. For example, the cathode electrode 16 may be the first electrode, the anode electrode 11 may be the second electrode, the ETL 15 may be the first carrier transport layer, and the HTL 13 may be the second carrier transport layer. Thus, the first electrode forming step may be the cathode electrode forming step, the second electrode forming step may be the anode electrode forming step, the first carrier transport layer forming step may be an electron transport layer forming step, and the second carrier transport layer forming step may be a hole transport layer forming step. In a case where the cathode electrode 16 is the first electrode and the first carrier injection layer is the HIL 12, the first carrier injection layer forming step is performed after the electron transport layer forming step. In a case where the cathode electrode 16 is the first electrode and the light-emitting element 1 includes an electron injection layer, the first carrier injection layer forming step may be an electron injection layer forming step.

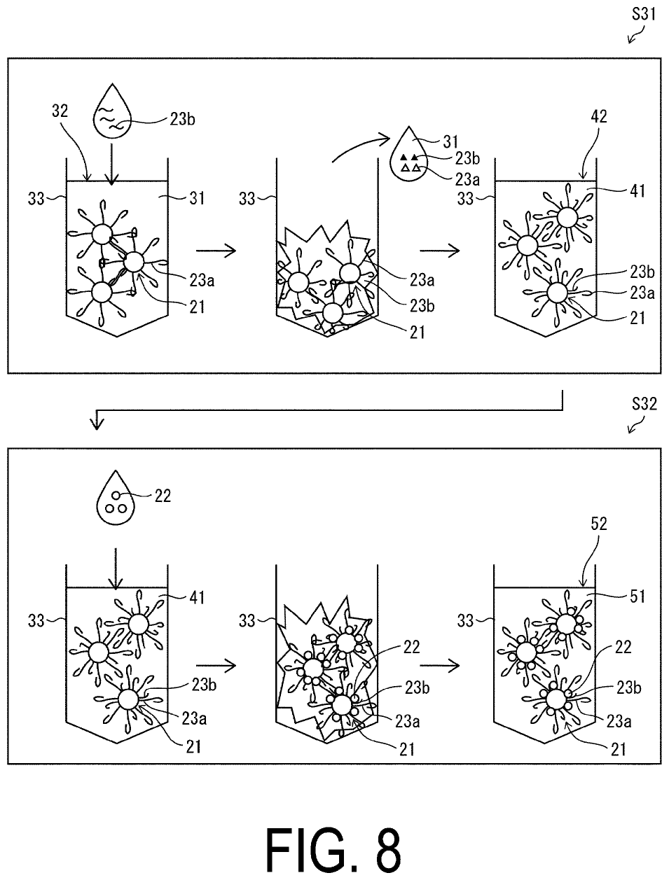

As illustrated in FIG. 7, in the method for manufacturing the light-emitting element 1 according to the present embodiment, first, the anode electrode 11 is formed on the substrate 10 (step S1: a first electrode forming step, an anode electrode forming step). Next, the HIL 2 is formed (step S2: a first carrier injection layer forming step, a hole injection layer forming step). Next, the HTL 13 is formed (step S3: a first carrier transport layer forming step, a hole transport layer forming step). In parallel, a QD dispersion 52 (third quantum dot dispersion) illustrated in FIG. 8 to be described below is produced (prepared) (step S11: a quantum dot dispersion production step). As illustrated in FIG. 8, the QD dispersion 52 includes the QD 21, the halogen ligand 22, the first organic ligand 23a composed of a first organic compound, the second organic ligand 23b composed of a second organic compound, and a solvent 51.

Subsequently, the EML 14 is formed using the QD dispersion 52 (step S4: a light-emitting layer forming step). In step S4, first, the QD dispersion 52 is applied onto the HTL 13 to form a coating film of the QD dispersion 52 (step S21: a quantum dot dispersion applying step). Note that as a method for forming the coating film, any method such as a bar coating method, a spin coating method, or an ink-jet method may be appropriately selected. Next, the solvent 51 is removed by heating or the like to dry the coating film (step S22: a solvent removal step).

Subsequently, the ETL 15 is formed (step S5: a second carrier transport layer forming step, an electron transport layer forming step). Next, the cathode electrode 16 is formed (step S6: a second electrode forming step, a cathode electrode forming step). In this way, the light-emitting element 1 is manufactured.

Note that in a case where the light-emitting element 1 is a part of a display device, a red light-emitting layer including a red QD, a green light-emitting layer including a green QD, and a blue light-emitting layer including a blue QD are separately formed in step S4 above using a process similar to a process in the related art, such as photolithography.

In addition, after step S1 and before step S2, an edge cover forming step of forming an edge cover that covers an edge of a lower electrode (the anode electrode 11 in the present embodiment) may be performed as necessary.

For example, a vapor deposition method, a sputtering method, or the like is used for formation of the anode electrode 11 in step S1 and formation of the cathode electrode 16 in step S6.

In the formation of the HTL 13 in step S3, for example, a coating method, a sputtering method, a sol-gel method, or the like is used. A coating method is used in the formation of the ETL 15 in step S5, for example.

As illustrated in FIG. 7, the QD dispersion 52 used in step S4 is produced in advance prior to performing step S4. FIG. 8 is a cross-sectional view schematically illustrating an example of step S11 (the quantum dot dispersion production step) illustrated in FIG. 7.

As described above, an organic ligand is often coordinated as an initial ligand to a synthesized or commercially obtained QD. As described above, a commercially available QD is generally provided in the form of a QD dispersion that includes an organic ligand.

On the other hand, a QD dispersion obtained by the wet method includes an organic ligand used in the synthesis of the QD. In the present embodiment, description will be given using a case where the QD dispersion thus synthesized or commercially obtained is used as an initial QD dispersion 32 illustrated in FIG. 8, and the initial ligand is the first organic ligand 23a, as an example. However, the present embodiment is not limited to the above configuration.

In a case where the initial ligand is the first organic ligand 23a, in step S11, first, organic ligand substitution treatment is performed to substitute a part of the first organic ligand 23a with the second organic ligand 23b (ligand exchange) (step S31: an organic ligand substitution treatment step, an organic compound substitution treatment step). The method for substituting a part of the first organic ligand 23a with the second organic ligand 23b is not particularly limited, and various known methods for substituting an organic ligand with another organic ligand can be used.

As an example, in step S31, first, as illustrated in FIG. 8, for example, the initial QD dispersion 32 (first quantum dot dispersion) including the QD 21, the first organic ligand 23a (initial ligand), and an initial solvent 31 is collected in a reaction vessel 33 such as a centrifuge tube. Note that here, the initial solvent 31 is a solvent included in the initial QD dispersion 32, and indicates a solvent used in the synthesized or commercially obtained QD dispersion.

Next, a second organic ligand solution including the second organic ligand 23b is added to the initial QD dispersion 32, and the initial QD dispersion 32 and the second organic ligand solution are mixed by ultrasonic treatment or the like. This can substitute a part of the first organic ligand 23a with the second organic ligand 23b (ligand exchange).

In the present embodiment, dodecanethiol is used as an example of the second organic ligand 23b as described below. Dodecanethiol is a liquid, and in a case where the second organic ligand 23b is a liquid like dodecanethiol, the second organic ligand 23b itself is used as the second organic ligand solution.

Note that conditions used for the ligand exchange (organic ligand substitution treatment), such as a concentration and addition amount of the second organic ligand 23b in the second organic ligand solution and a mixing time of the initial QD dispersion 32 and the second organic ligand solution, are not particularly limited. These conditions only need be appropriately set depending on types and the like of these organic ligands 23 in such a manner that a proportion of each of the first organic ligand 23a and the second organic ligand 23b to the total amount of the first organic ligand 23a and the second organic ligand 23b becomes a desired proportion.

Next, centrifugation is performed and a supernatant is removed. This removes a free first organic ligand 23a and a free second organic ligand 23b which are not coordinated to the QD 21.

Note that at this time, the QDs 21 may be washing-separated as necessary. Here, the washing separation of the QDs 21 indicates a step of separating the QD 21 by controlling the degree of aggregation due to a difference in coordination state of ligands coordinated to the QDs 21 by a ratio of a non-polar solvent such as toluene and a polar solvent such as ethanol. Even when the particle sizes of the QDs 21 are uniform, by controlling a ratio of solvents such as toluene and ethanol, an aggregation state of the QDs 21 can be changed depending on a difference in types or amounts of the organic ligands coordinated to the surfaces of the QDs 21. This makes it possible to sort the QD 21 having excellent light-emission characteristics. Note that after the supernatant is removed by centrifugation, a treatment in which a solvent such as toluene or ethanol is added and centrifugation is performed may be performed a plurality of times.

After removal of the supernatant by centrifugation, the precipitated QD 21 is redispersed in a solvent 41. As the solvent 41, for example, a non-polar solvent such as hexane, cyclohexane or octane is used. In this way, a QD dispersion 42 (second quantum dot dispersion) including the solvent 41, the QD 21, and the organic ligands 23 including the first organic ligand 23a and the second organic ligand 23b is produced (prepared).

Next, halogen ligand substitution treatment is performed to substitute a part of the organic ligands 23 with the halogen ligand 22 (ligand exchange) (step S32: a halogen ligand substitution treatment step, a halogen element substitution treatment step).

The method for substituting a part of the organic ligands 23 with the halogen ligand 22 is not particularly limited, and various known methods for substituting an organic ligand with a halogen ligand can be used.

As an example, in step S32, a halogen ligand solution containing the halogen ligand 22 is added to the QD dispersion 42 as a solution containing a halogen element, and the QD dispersion 42 and the halogen ligand solution are stirred and mixed by a mixer such as a vortex mixer.

In this way, a part of the plurality of types of organic ligands 23 including the first organic ligand 23a and the second organic ligand 23b can be substituted (ligand exchange) with the halogen ligand 22 including a halogen element. In other words, a part of the plurality of types of organic ligands 23 can be substituted with the halogen element included in the halogen ligand 22.

Note that after the halogen ligand solution is added to the QD dispersion 42, heating may be performed as necessary. Conditions used for the ligand exchange (halogen ligand substitution treatment), such as the concentration and addition amount of the halogen ligand solution, a stirring time (mixing time), a heating temperature, and a heating time, are not particularly limited. These conditions only need be appropriately set depending on the type of the halogen ligand solution, the types of the organic ligands 23, and the like in such a manner that a proportion of each of the halogen ligand 22 and the organic ligands 23 to the total amount of the halogen ligand 22 and the organic ligands 23 becomes a desired proportion.

Thereafter, the obtained mixed solution is allowed to stand at room temperature, and then a polar solvent such as ethanol is added as a poor solvent to precipitate the QD 21, followed by centrifugation. Note that the treatment of adding the poor solvent to precipitate the QD 21 and performing centrifugation may be performed a plurality of times. After the centrifugation, the supernatant is removed, and the precipitated QD 21 is redispersed in a solvent 51. These series of treatments are all performed under an inert atmosphere such as nitrogen.

In this way, the QD dispersion 52 including the solvent 51, the QD 21, and the organic ligands 23 including the first organic ligand 23a and the second organic ligand 23b can be obtained. As the solvent 51, for example, a non-polar solvent such as hexane, cyclohexane, or octane is used.

Note that the halogen ligand solution is prepared in advance before performing step S32. A manufacturing process of the light-emitting element 1 according to the present embodiment includes a halogen ligand solution preparation step before step S32.

In a case where the halogen ligand 22 is, for example, an F ligand, the halogen ligand solution can be prepared by, for example, the following method.

First, for example, ethanol is collected in a reaction vessel such as a screw bottle, and anhydrous ZnF₂ is added thereto and stirred. Next, the reaction vessel is subjected to ultrasonic waves to sufficiently mix the anhydrous ZnF₂ and ethanol in the reaction vessel, followed by heating to dissolve the anhydrous ZnF₂ in the reaction vessel into ethanol. Thereafter, a solution portion in the reaction vessel is filtered to prepare a ZnF₂ solution as the halogen ligand solution.

Note that when ZnCl₂ and ethanol are mixed, a ZnCl₂ solution can be prepared as the halogen ligand solution.

FIG. 9 is a graph showing EQEs with respect to current densities of the light-emitting element 1 according to an example of the present embodiment in which a part of the initial ligand is substituted with dodecanethiol and the F ligand, and light-emitting elements for comparison in which a part of the initial ligand is substituted with dodecanethiol or F⁻.

Note that in FIG. 9, “DDT treatment+F treatment” indicated by “∘” indicates the EQE with respect to the current density of the light-emitting element 1 according to the example of the present embodiment. In FIG. 9, “DDT treatment only” indicated by “Δ” and “F treatment only” indicated by “□” indicate the EQEs with respect to the current densities of the light-emitting elements for comparison, respectively.

Here, “DDT treatment+F treatment” indicates that the EML 14 was formed by using the QD dispersion 52 obtained by substituting a part of the initial ligand with dodecanethiol (DDT) in step S31 and substituting a part of these organic ligands with the F ligand in step S32. In the DDT treatment, first, dodecanethiol (DDF) was added to the initial QD dispersion 32, ultrasonic treatment was performed, and then washing separation was performed using toluene, ethanol, and methanol. Next, the supernatant was removed by centrifugation, and the precipitated QD 21 was redispersed in cyclohexane. In the F treatment, first, ZnF₂ solution was added to the QD dispersion 42 obtained by the DDT treatment, and the mixture was stirred with a vortex mixer for several seconds and then allowed to stand at room temperature for several minutes, and ethanol was added thereto to precipitate the QD 21. Next, the supernatant was removed by centrifugation, and the precipitated QD 21 was redispersed in hexane.

“∘” indicates a measurement result when the light-emitting element 1 including the EML 14 including the F ligand and the two types of organic ligands 23 formed by using the QD dispersion 52 obtained as described above is used.

“DDT treatment only” indicates that the EML 14 is formed by using the QD dispersion 42 obtained by performing the above-described DDT treatment in step S31 and substituting a part of the initial ligand with dodecanethiol as the QD dispersion for comparison. That is, “Δ” indicates a measurement result when the light-emitting element for comparison including the EML 14 including only the two types of organic ligands 23 as the ligand is used.

“F treatment only” indicates that the EML 14 was formed by using, as the QD dispersion for comparison, a QD dispersion obtained by performing the above-described F treatment on the initial QD dispersion 32 without performing the organic ligand substitution treatment to substitute a part of the initial ligand with the F ligand. That is, “□” indicates a measurement result when the light-emitting element for comparison including the EML 14 including only the F ligand including the F element as the ligand is used.

Note that as conditions other than the conditions described above, the same conditions were used, and in any case, the same type of blue QD was used for the QD 21, PEDOT:PSS was used for the HIL 12, PVK was used for the HTL 13, and ZnO was used for the ETL 15. ITO was used for the anode electrode 11, and Al was used for the cathode electrode 16.

As a result, as shown in FIG. 9, the EQE of the light-emitting element 1 subjected to the DDT treatment+the F treatment was increased as compared with the light-emitting element for comparison subjected to only the DDT treatment or only the F treatment. Note that the light-emitting element 1 and the light-emitting elements for comparison have the same configuration except for the EML 14. Thus, it is found that the increase in the EQE is caused by the DDT treatment+the F treatment (that is, the organic ligand substitution treatment+the halogen ligand substitution treatment), and is not caused by the other conditions. Accordingly, according to the present embodiment, as described above, it is found that when the light-emitting element 1 includes the EML 14 including the QD 21, the halogen element, and the plurality of types of organic compounds, it is possible to achieve a high EQE.

### Modified Example

FIG. 1 illustrates an example in which the anode electrode 11 is a lower electrode, the cathode electrode 16 is an upper electrode, and the ETL 15 is provided on the EML 14. However, the disclosure is not limited thereto. FIG. 1 illustrates an example in which the light-emitting element 1 has a configuration in which the substrate 10, the anode electrode 11, the HIL 12, the HTL 13, the EML 14, the ETL 15, and the cathode electrode 16 are layered in this order from the lower layer side. However, the light-emitting element 1 according to the present embodiment is not limited thereto.

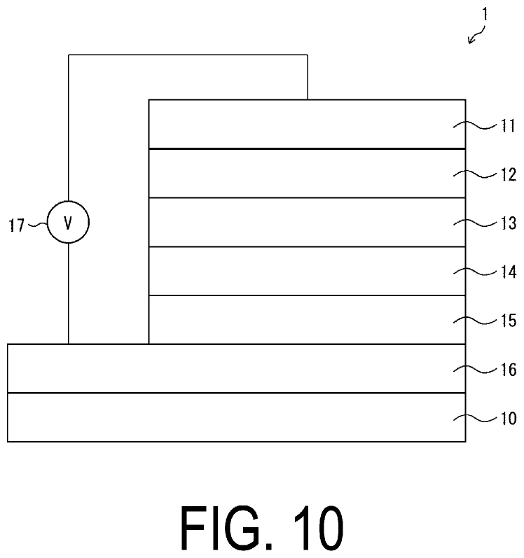

FIG. 10 is a view illustrating an example of a layered structure of a light-emitting element 1 according to a present modified example.

As one example, the light-emitting element 1 illustrated in FIG. 10 has a configuration in which the substrate 10, the cathode electrode 16, the ETL 15, the EML 14, the HTL 13, the HIL 12, and the anode electrode 11 are layered in this order from the lower layer side. In this way, in the light-emitting element 1, the cathode electrode 16 may be the lower electrode, the anode electrode 11 may be the upper electrode, and the ETL 15 may be provided below the EML 14.

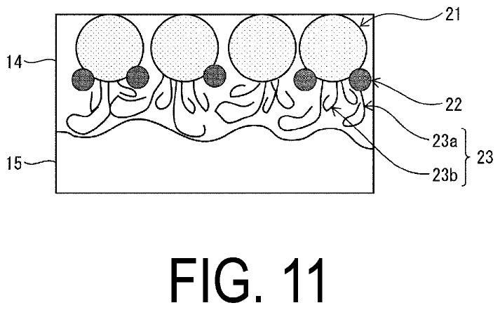

FIG. 11 is a partially enlarged cross-sectional view schematically illustrating a schematic configuration of a main part of the light-emitting element 1 according to the present modified example.

As described above, the surface of the ETL 15 using the element-substituted ZnO tends to be roughened. However, even when the base of the EML 14 is the ETL 15 using element-substituted ZnO, which is likely to cause surface roughness, according to the present modified example, when the QD dispersion 52 is applied onto the ETL 15, the irregularities of the surface of the ETL 15 can be suppressed. Thus, as illustrated in FIGS. 10 and 11, even when the ETL 15 using the element-substituted ZnO is provided below the EML 14, the electron injection efficiency can be improved and the effect of improving the EQE can be further enhanced.

The disclosure is not limited to the embodiment described above, and various modifications can be made within the scope of the claims. Embodiments obtained by appropriately combining disclosed technical approaches also fall within the technical scope of the disclosure. Furthermore, novel technical features can be formed by combining the disclosed technical approaches.

1. A light-emitting element comprising:
a light-emitting layer, the light-emitting layer including a quantum dot, a halogen element, and a plurality of types of organic compounds.

2. The light-emitting element according to claim 1,
wherein the plurality of types of organic compounds have different lengths of main chains or side chains.

3. The light-emitting element according to claim 1,
wherein the plurality of types of organic compounds include a compound including at least one functional group selected from the group consisting of an amino group, a phosphonic group, a phosphine group, a phosphine oxide group, a carboxyl group, and a thiol group.

4. The light-emitting element according to claim 1,
wherein the plurality of types of organic compounds include a compound including a thiol group.

5. The light-emitting element according to claim 1,
wherein the plurality of types of organic compounds include at least one compound selected from the group consisting of dodecanethiol, octanethiol, oleylamine, dodecylamine, trioctylphosphine oxide, trioctylphosphine, and tributylphosphine.

6. The light-emitting element according to claim 1,
wherein the plurality of types of organic compounds include dodecanethiol.

7. The light-emitting element according to claim 1,
wherein the plurality of types of organic compounds include a compound having a molecular chain in which a length of a molecular chain between terminal groups is different by 10% or more from a length of any one molecular chain between terminal groups in any one of the plurality of types of organic compounds.

8. The light-emitting element according to claim 1,
wherein the plurality of types of organic compounds include a compound having a molecular chain in which a length of a molecular chain between terminal groups is different by 30% or more from a length of any one molecular chain between terminal groups in any one of the plurality of types of organic compounds.

9. The light-emitting element according to claim 1,
wherein the plurality of types of organic compounds include a compound having a molecular chain in which a length of a molecular chain between terminal groups is different by 50% or more from a length of any one molecular chain between terminal groups in any one of the plurality of types of organic compounds.

10. The light-emitting element according to claim 1,
wherein the plurality of types of organic compounds include a compound having a molecular chain in which a length of a molecular chain between terminal groups is different by 70% or more from a length of any one molecular chain between terminal groups in any one of the plurality of types of organic compounds.

11. The light-emitting element according to claim 1,
wherein the plurality of types of organic compounds include a compound having 8 to 15 carbon atoms.

12. The light-emitting element according to claim 1,
wherein the halogen element includes at least one element selected from the group consisting of fluorine, chlorine, and bromine.

13. The light-emitting element according to claim 1, further comprising
an electron transport layer adjacent to the light-emitting layer,
wherein the electron transport layer includes a zinc oxide including zinc and a metal element other than zinc.

14. The light-emitting element according to claim 13,
wherein the zinc oxide includes at least one selected from the group consisting of MgZnO, LiZnO, and MgLiZnO.

15. The light-emitting element according to claim 13,
wherein the electron transport layer is provided on the light-emitting layer.

16. The light-emitting element according to claim 13,
wherein the electron transport layer is provided below the light-emitting layer.

17. The light-emitting element according to claim 13,
wherein a lower end of a conduction band of the quantum dot is shallower than a lower end of a conduction band of the electron transport layer.

18. The light-emitting element according to claim 1,
wherein the quantum dot includes a core and a shell, and
the shell includes ZnS.

19. A method for manufacturing a light-emitting element, comprising:
performing an organic compound substitution treatment of mixing a first quantum dot dispersion including quantum dots and a first organic compound with a second organic compound to substitute a part of the first organic compound with the second organic compound to produce a second quantum dot dispersion including the quantum dots and a plurality of types of organic compounds including the first organic compound and the second organic compound;
performing a halogen element substitution treatment of mixing the second quantum dot dispersion with a solution containing a halogen element to substitute a part of the plurality of types of organic compounds including the first organic compound and the second organic compound with the halogen element to produce a third quantum dot dispersion including the quantum dots, the plurality of types of organic compounds including the first organic compound and the second organic compound, and the halogen element; and
performing light-emitting layer formation of using the third quantum dot dispersion to form a light-emitting layer including the quantum dots, the halogen element, and the plurality of types of organic compounds.
